(19) United States
(12) Patent Application Publication
(10) Pub. No.: US 2010/0203242 A1
(43) Pub. Date: Aug. 12, 2010

(54) SELF-CLEANING SUSCEPTOR FOR SOLAR CELL PROCESSING

(75) Inventor: PETER BORDEN, San Mateo, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/367,333

(22) Filed: Feb. 6, 2009

(51) Int. Cl. C23C 16/458

(52) U.S. Cl. 427/248.1; 118/730

(57) ABSTRACT

An apparatus and method for processing substrates are provided. In one embodiment, a susceptor for an apparatus for processing a substrate includes a plurality of segments aligned to form a substrate support surface, each segment having one or more flat surfaces for supporting the substrate, and an opening that extends along an axis of rotation. The susceptor also includes a plurality of rotatable shafts, each shaft positioned in the opening of one of the segments. The method of processing a batch of substrates includes transferring at least one substrate in the batch into a processing chamber and onto a susceptor, processing the at least one substrate within the chamber, transferring the at least one substrate out of the processing chamber, and removing debris from the substrate support surface by rotating the segments to dump any debris on the substrate support surface onto a chamber floor where it will remain during further processing.

### BACKGROUND OF THE INVENTION

1. Field of the Invention

Embodiments of the invention generally relate to an apparatus and a method for forming a solar cell device. Some embodiments are particularly useful for fabrication of crystalline silicon solar cells.

2. Description of the Related Art

Photovoltaics (PV) or solar cells are devices which convert sunlight into direct current (DC) electrical power. A typical PV cell includes a p-type silicon wafer, substrate, or sheet typically less than about 0.3 mm thick with a thin layer of an n-type silicon material disposed on top of the p-type substrate. The generated voltage, or photo-voltage, and generated current by the photovoltaic device are dependent on the material properties of the substrate and p-n junction, the interfacial properties between deposited layers, and the surface area of the device. When exposed to sunlight (consisting of energy from photons), the p-n junction of the PV cell generates pairs of free electrons and holes. The electric field formed across the depletion region of the p-n junction separates the free electrons and holes, creating a current. A circuit from n-side to p-side allows the flow of electrons when the PV cell is connected to an electrical load. Electrical power is the product of the voltage times the current generated as the electrons and holes move through an external load and eventually recombine. Solar cells generate a specific amount of power and cells are tiled into modules sized to deliver the desired amount of system power. Solar modules are created by connecting a number of solar cells and are then joined into panels with specific frames and connectors.

The photovoltaic (PV) market has experienced growth with annual growth rates exceeding above 30% for the last ten years. Some articles have suggested that solar cell power production world wide may exceed 10 GWp in the near future. It has been estimated that more than 90% of all photovoltaic modules are silicon substrate based. The high market growth rate in combination with the need to substantially reduce solar electricity costs has resulted in a number of serious challenges for silicon substrate production development for photovoltaics.

Silicon solar cells are made on thin substrates, generally between 160-220 microns, and trending to 120 microns, such as between 120-150 microns. Thus, solar cell substrates are increasingly prone to breakage in process chambers. Furthermore, wafer edges are not dressed. Therefore, any processing system may include considerations for removing broken substrates. Some systems employ substrate carriers, which then carry broken substrates through the system. However, systems that use lift pins to move substrates cannot readily remove broken substrates.

### SUMMARY OF THE INVENTION

In one embodiment of the invention, a susceptor for an apparatus for processing a substrate is provided. The susceptor includes a plurality of segments aligned to form a substrate support surface, each segment having one or more flat surfaces for supporting the substrate, and an opening that extends along an axis of rotation. The susceptor also includes a plurality of rotatable shafts, each shaft positioned in the opening of one of the segments.

In another embodiment of the invention, an apparatus for processing a substrate is provided. The apparatus includes a processing chamber and a susceptor located within the chamber. The susceptor includes a plurality of segments aligned to form a substrate support surface, each segment having one or more flat surfaces for supporting the substrate, and an opening that extends along an axis of rotation. The susceptor also includes a plurality of rotatable shafts, each shaft positioned in the opening of one of the segments.

In yet another embodiment of the invention, a method of processing a batch of substrates is provided. The method includes transferring at least one substrate in the batch into a processing chamber and onto a susceptor. The susceptor includes a plurality of segments aligned to form a substrate support surface, each segment having one or more flat surfaces for supporting the substrate, and an opening that extends along an axis of rotation. The susceptor also includes a plurality of rotatable shafts, each shaft positioned in the opening of one of the segments. The method also includes processing the at least one substrate within the chamber, transferring the at least one substrate out of the processing chamber, and removing debris from the substrate support surface. The removing debris step includes rotating the segments to dump any debris on the substrate support surface onto a chamber floor where it will remain during further processing. The previous steps of the method are repeated until the last substrate in the batch is processed.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a plan view of a cluster tool that may be used according to one embodiment described herein.

FIG. 2 is a plan view of a substrate support element according to one embodiment described herein.

FIG. 3 is a plan view of the cluster tool illustrated in FIG. 1 which illustrates a substrate transferring path according to one embodiment described herein.

FIG. 4 is a schematic isometric view of the processing system illustrated in FIG. 1.

FIG. 5 is a schematic cross-sectional view of one embodiment of a PECVD type processing chamber according to one embodiment described herein.

FIG. 6 is a schematic cross-sectional view of one embodiment of a PECVD type processing chamber according to one embodiment described herein.

FIG. 7A a side view of a susceptor according to one embodiment described herein.

FIG. 7B is a side view of the susceptor illustrated in FIG. 7B in which substrates are transported according to one embodiment described herein.

FIG. 7C is a plan view of the susceptor illustrated in FIG. 7B in which substrates are transported according to one embodiment described herein.

### DETAILED DESCRIPTION

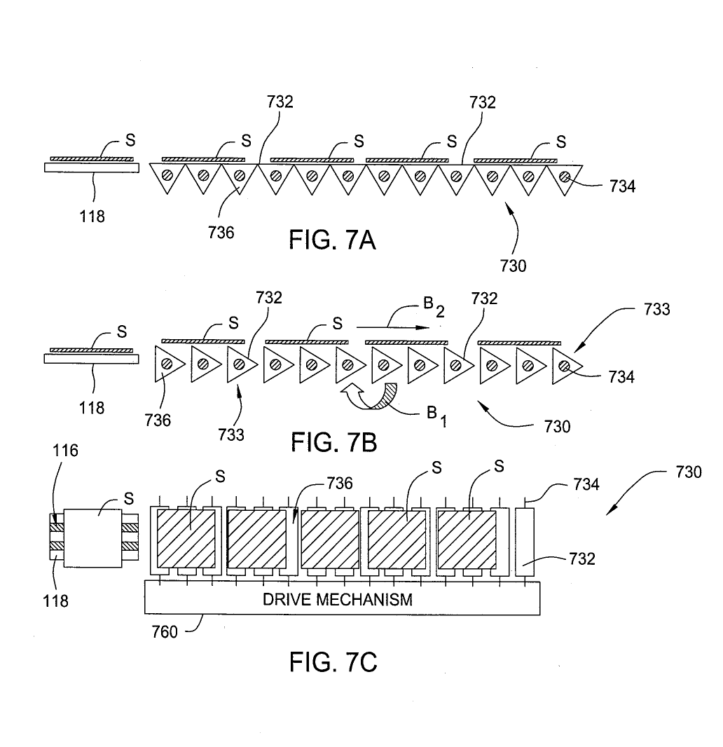

Embodiments of the present invention generally provide a susceptor for processing a substrate that may be used in various chambers, systems, and processing tools, such as a cluster tool, for in-situ processing of a film stack used to form regions of a solar cell device. In one configuration, the film stack formed on each of the substrates in the batch contains one or more passivating or dielectric layers and one or more metal layers that are deposited and further processed within various processing chambers contained in the substrate processing system. The processing chamber has a susceptor for supporting and processing the substrates. In some embodiments of the invention, the susceptor may also transport substrates in and out of processing chambers (FIGS. 7A-7C).

The processing chambers may be, for example, physical vapor deposition (PVD) or sputtering chambers, plasma enhanced chemical vapor deposition (PECVD) chambers, hot wire chemical vapor deposition (HWCVD) chambers, ion implant/doping chambers, plasma nitridation chambers, atomic layer deposition (ALD) chambers, plasma or vapor chemical etching chambers, laser anneal chambers, rapid thermal oxidation (RTO) chamber, rapid thermal nitridation (RTN) chamber, rapid thermal annealing (RTA) chamber, a vapor etching chamber, a forming gas or hydrogen annealer, a plasma cleaning chamber, and/or other similar processing chambers. The substrate processing system may include a deposition chamber in which a batch of substrates is exposed to one or more gas-phase materials or an RF plasma. In one embodiment, a cluster tool includes at least one plasma enhanced chemical vapor deposition (PECVD) process chamber that has been adapted to process multiple substrates at once and has a segmented susceptor. In one embodiment, a batch of solar cell substrates are simultaneously transferred in a vacuum or inert environment to prevent contamination from affecting the solar cell formation process and improve substrate throughput.

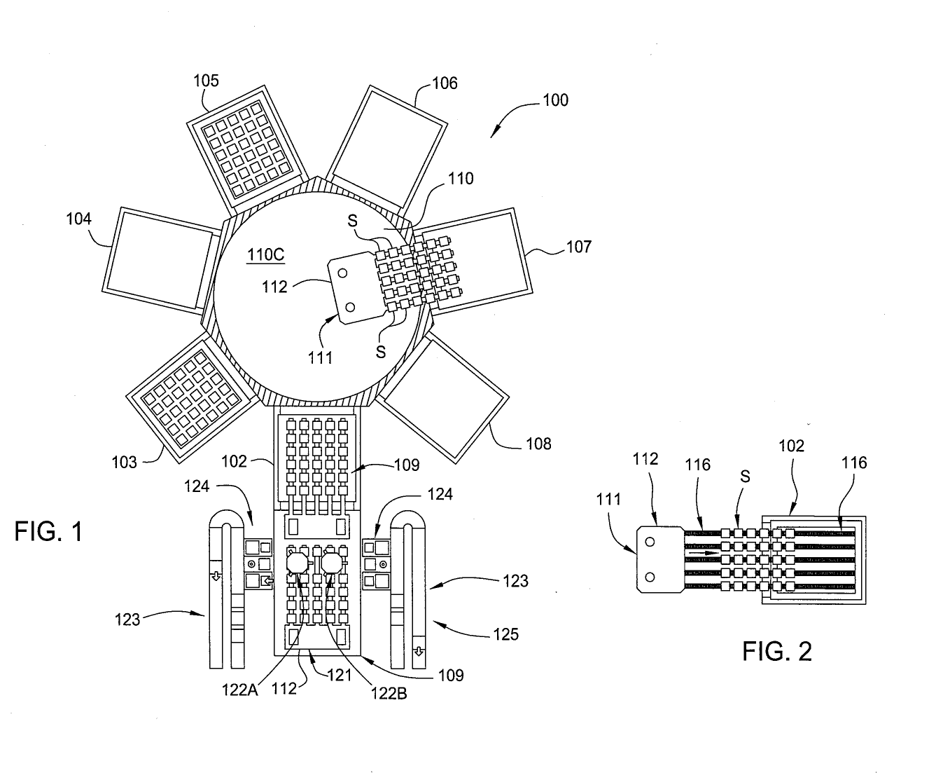

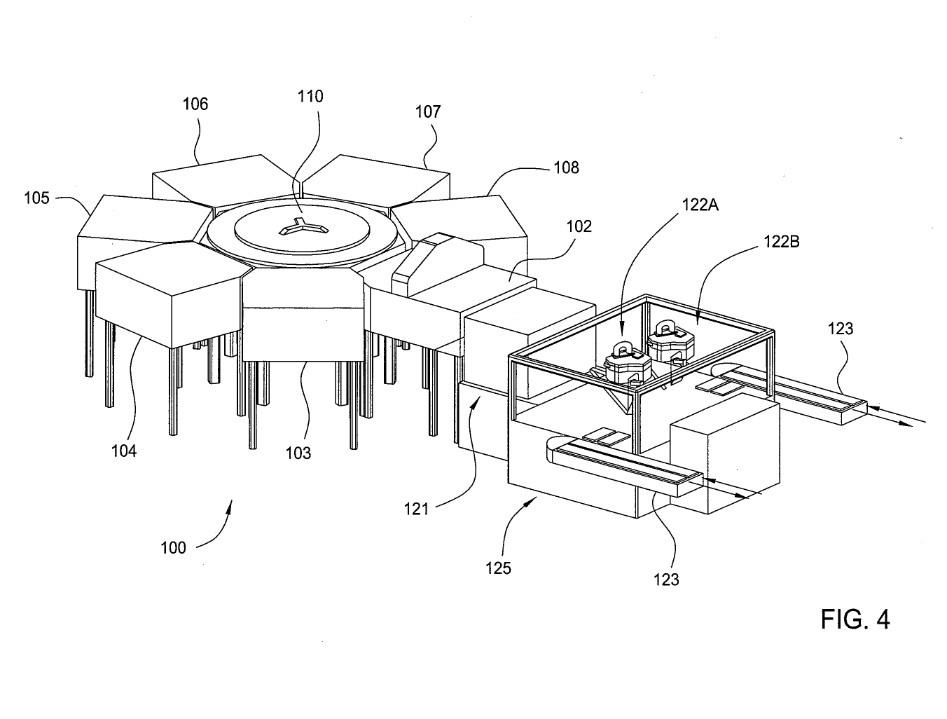

FIGS. 1 and 4 illustrate an exemplary substrate processing system 100 that may be suitable for performing solar cell processing according to embodiments of the invention. One suitable processing system that may be adapted to perform one or more of the processing steps and/or transferring steps discussed herein is a processing platform, such as a Gen. 5, Gen. 6, or Gen. 8.5 processing platform, available from the AKT division of Applied Materials, Inc., located in Santa Clara, Calif. The substrate processing system 100 typically includes a transfer chamber 110 that is coupled to a substrate transport interface 125 via a load lock chamber 102. The transfer chamber 110 generally contains a robot 111 that is adapted to transfer substrates among a plurality of processing chambers (e.g., reference numerals 103-108) and the load lock chamber 102 that is generally selectively sealably coupled to the transferring region 110C of the transfer chamber 110 by use of a slit valve (not shown).

Each slit valve is generally configured to selectively isolate the processing region in each of the processing chambers 103-108 from the transferring region 110C, and are generally disposed adjacent to the interface between the processing chambers 103-108 and the transfer chamber 110. In one embodiment, the transfer chamber 110 is maintained at a vacuum condition to eliminate or minimize pressure differences between the transfer chamber 110 and the individual processing chambers 103-108, which are typically used to process the substrates under a vacuum condition. In alternate embodiment, the transfer chamber 110 and the individual processing chambers 103-108 are used to process the substrates in a clean and inert atmospheric pressure environment. It should be noted that the number and orientation of processing chambers (e.g., reference numerals 103-108) is not intended to be limiting as to the scope of the invention, since these configurationally details could be adjusted without deviating from the basic scope of the invention described herein.

FIG. 1 is plan view of one embodiment of a substrate processing system 100 that contains six processing chambers (e.g., reference numerals 103-108), a load lock chamber 102, and a robot 111 disposed within the transferring region 110C of the transfer chamber 110. In one configuration, the processing chambers 103-108 are selected from the group consisting of a physical vapor deposition (PVD) chamber, a plasma enhanced chemical vapor deposition (PECVD) chamber, a hot wire chemical vapor deposition (HWCVD) chamber, a plasma nitridation chamber (DPN), a ion implant/doping chamber, an atomic layer deposition (ALD) chamber, a plasma etching chamber, laser anneal chamber, rapid thermal oxidation/nitridation (RTO/N) chamber, rapid thermal annealing (RTA) chamber, a substrate reorientation chamber, a vapor etching chamber, a forming gas or hydrogen annealer, and/or a plasma cleaning chamber.

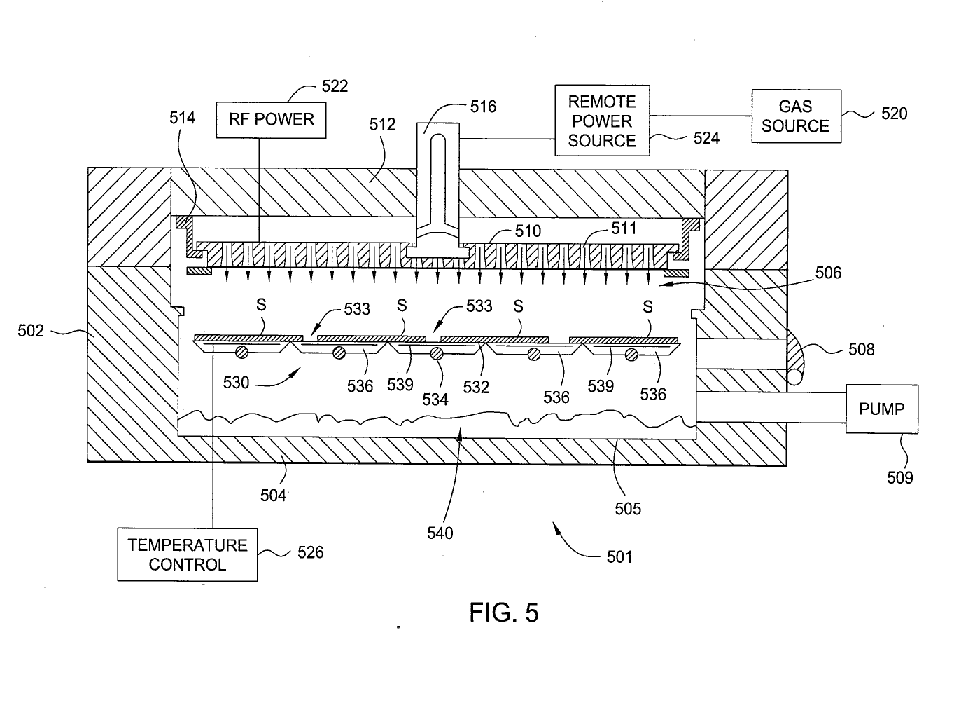

According to one embodiment of the invention, the substrate processing system 100 includes a first process chamber 103 and a second process chamber 108 (e.g. FIGS. 1 and 4). In one embodiment, the first process chamber 103 is configured to deposit a specific type of film and the second process chamber 108 is configured to form a different type of film(s) on a substrate surface. For example, the first process chamber 103 can be used to process one or more silicon-containing films and the second process chamber 108 can be used to process one or more metal-containing films to form a high quality solar cell junction. An example of an exemplary PECVD type processing chamber that may be positioned at one or more of the processing chambers 103-108 positions is illustrated and discussed in conjunction with in FIG. 5 shown below. However, multiple processes may be performed in a single chamber, without transfer to a second chamber. For example, the silicon surface can be vapor etched, followed by a rapid thermal oxidation, or an amorphous silicon layer may be deposited followed by a silicon nitride layer (the former through thermal or plasma decomposition of silane and the latter through thermal or plasma decomposition of silane with addition of ammonia).

FIGS. 1-4 illustrate one embodiment of a substrate processing system 100 that is adapted to transfer and process a plurality of solar cell substrates, hereafter substrates “S”, in groups, or batches, within the processing system 100. FIG. 1 is a plan view of a single transfer chamber 110 type processing system that is adapted to transfer and process a batch of substrates. FIG. 4 is a schematic isometric view of the processing system 100 illustrated in FIG. 1. In this configuration multiple substrates can be transferred, supported, and processed at the same time to improve the system throughput, reduce the number of required transferring steps, and improve the cost of ownership associated with processing and forming a solar cell device.

Additionally, in this configuration, the robotic device 109 and robot 111 are designed to receive and transfer multiple substrates S without the use of a carrier to support and retain the substrates S. This provides several benefits, including reduced cost, eliminating the need to clean and maintain carriers, and eliminating the need to find a carrier material mutually compatible with the process conditions in all process modules. In order to receive and process the substrates S, the load lock chamber 102 and processing chambers 103-108 are configured to receive and support each of the individual substrates S in the batch. In this configuration, the substrates are supported and/or retained on substrate supporting devices (e.g., substrate support surface 532 in FIG. 5) contained within the load lock chamber 102 and processing chambers 103-108.

FIG. 2 illustrates one embodiment of a substrate support element 112 that contains a plurality of substrate conveyors 116 that are used to support and transfer the batch of substrates, such as thirty substrates, to a position within processing chamber. In one example, as shown in FIG. 2, the substrate conveyors 116 are adapted to transfer a batch of substrates to a position within a load lock chamber 102. The substrate conveyors 116 are generally belts or other similar devices that are moved by one or more actuators found in the substrate support element 112, or within the load lock chamber 102 or the processing chambers 103-108, to cause each of substrates in the batch to be moved simultaneously to a desired position within the load lock chamber 102 or the processing chambers 103-108 by movement of the belts. In another embodiment, the substrate conveyors 116 are moved to cause each of the substrates in the batch to be moved simultaneously to a desired position on a susceptor and the susceptor transfers the substrates in the batch to a desired position within the processing chambers 103-108 (FIGS. 7A-7C).

In one embodiment of the processing system 100, the load lock chamber 102 is coupled to the transfer chamber 110 and a substrate loading module 125. In general, the substrate loading module 125 contains one or more robots, such as robots 122A, 122B, that are adapted to receive substrates from the modular conveyor 123 and transfer each of the substrates one at a time, or in groups, to a desired position within the hand-off position 121 so that the loading robotic device 109 can move the substrates into the load lock chamber 102. In one embodiment, the loading robotic device 109 is adapted to position a batch of substrates, by the robots 122A, 122B, within the load lock chamber 102. In one example, the load lock chamber 102 comprises a plurality of isolatable regions that allow the unimpeded movement of substrates S into and out-of the load lock chamber 102 from the transfer chamber or the substrate loading module 125.

The substrate loading module 125 also generally contains a modular conveyor 123 that is adapted to receive substrates S from the various conveyance systems contained in the solar cell production fab. In general, the modular conveyor 123 is an inter-tool conveyor system that is used to transfer solar cell substrates S between the various processing systems 100 that are positioned in the solar cell fab to form various portions of the solar cell device, or from a cassette or stack of substrates placed in the system. In one example, the modular conveyor 123 is adapted to transfer stacks of solar cell substrates S to a receiving area 124 that is positioned to allow the transfer of substrates S between the robots 122A, 122B and the modular conveyor 123.

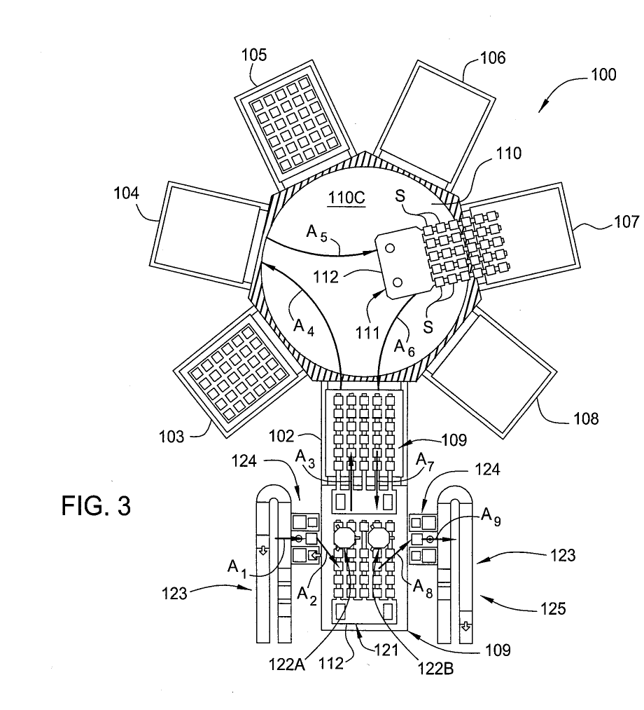

FIG. 3 illustrates an example of the transfer paths and steps that a batch of substrates may follow as the solar cell substrates are processed within the processing system 100 illustrated in FIG. 1. In this embodiment, a stack of substrates are removed from a modular conveyor 123 and transferred following the transfer path A₁ to a receiving area 124 so that the substrates S can be received by the robots 122A, 122B. Once the substrates S are positioned within the receiving area 124, the substrates are then transferred by the robot 122A following the transfer path A₂ to the substrate conveyors 116 formed on the substrate support element 112 of the robotic device 109 that is positioned within the hand-off position 121.

In one embodiment, the robot 122A positions each of the substrates transferred from the receiving area 124 into a desired position on substrate conveyors 116, as shown in FIG. 3. After filling up the substrate conveyors 116 with substrates S, the substrates are then transferred to the load lock chamber 102 by the robotic device 109 following the transfer path A₃. It should be noted that not all positions on a substrate conveyor 116 need to be filled during processing, for example, if a substrate broke in an earlier step, or in some cases a partial lot, or batch, of substrates are processed within the system. In some cases it may be desirable to insert one or more dummy substrates within a batch of substrates to minimize the exposure of the chamber components (e.g., susceptor) directly to the processing environment.

Next, after receiving the substrates in, for example, a sub-chamber of the load lock chamber 102 from the substrate conveyor 116, the sub-chamber is closed and pumped down to a desired pressure using a vacuum pump (not shown). After achieving a desired pressure in the sub-chamber, the substrates S are received by the substrate conveyor 116 formed on the substrate support element 112 of the robot 111 and then transferred to one of the processing chambers, such as processing chamber 104, following the transfer path A₄.

After receiving the substrates on the substrate supporting device, such as a susceptor, contained in a portion of the processing chamber 104, the processing chamber is isolated from the transfer chamber 110 for processing. In one example, a PECVD amorphous silicon deposition process is performed on the substrates S positioned in the processing chamber 104. After performing a desired solar cell formation process on the substrates, the substrates S are then received, and transferred by the robot 111 to another one of the processing chambers, such as processing chamber 107, following the transfer path A₅.

After receiving the substrates on a substrate supporting device, such as a susceptor, contained in a portion of the processing chamber 107, the processing chamber is isolated from the transfer chamber 110 to allow processing. In one example, a metallization type deposition process is performed on the substrates positioned in the processing chamber 107. After performing the desired solar cell formation process on the substrates, the substrates S are then transferred by the robot 111 to a region of the load lock chamber 102, such as a sub-chamber, following the transfer path A₆.

After receiving the substrates S and achieving a desired pressure in the sub-chamber, the substrates S are then transferred from the load lock chamber 102 using the substrate conveyors 116 formed on the robotic device 109 following the transfer path A₇ to a position within the hand-off position 121. Once the substrates are positioned within the hand-off position 121, the substrates are then transferred from the substrate conveyors 116 formed on the robotic device 109 to a receiving area 124 by the robot 122B following the transfer path A₈. After positioning the substrates in the receiving area 124 the substrates are then transferred to a modular conveyor 123 so that the processed substrates can be moved to other areas of the solar cell fab by following the transfer path A₉.

It should be noted that the number of transferring steps and processing steps discussed above (FIG. 3) are not intended to be limiting as to the scope of the invention described herein and can vary in the number of processes performed on the solar cell substrate, vary in the number of processing chambers that are used to form a solar cell, and vary in the order and sequence of steps without deviating from the basic idea disclosed herein. Also, in general the processing sequence performed on the substrates in one or more of the processing chambers 103-108 in the processing system 100 as discussed in conjunction with FIG. 3 may include PVD, PECVD, HWCVD, ALD, plasma etching, rapid thermal anneal (RTA), rapid thermal oxidation (RTO/N), laser anneal, plasma cleaning chambers, a substrate reorientation chamber, a vapor etching chamber, a forming gas or hydrogen annealer, and/or a plasma cleaning chamber.

FIG. 5 is a schematic cross-section view of one embodiment of a processing chamber, such as a PECVD chamber 501 in which one or more films can be deposited on each of the substrates in the batch. In one configuration, the PECVD chamber 501 is adapted to deposit one or more layers on each of the substrates S that are disposed on a susceptor 530, as shown in FIG. 5. One suitable plasma enhanced chemical vapor deposition chamber is available from Applied Materials, Inc., located in Santa Clara, Calif. It is contemplated that other deposition chambers, such as hot wire chemical vapor deposition (HWCVD), low pressure chemical vapor deposition (LPCVD), physical vapor deposition (PVD), evaporation, or other similar devices, including those from other manufacturers, may be utilized to practice the present invention. In one embodiment, the chamber 501 generally includes walls 502, a bottom 504, and a showerhead 510, and susceptor 530 which define a process volume 506.

The process volume is accessed through a valve 508 such that the batch of substrates, such as a plurality of substrates disposed on an end effector of robot 112, such as substrate conveyor 116, may be transferred in and out of the PECVD chamber 501. The susceptor 530 includes plurality of segments 536 that are aligned to form a substrate support surface 532. Each segment 536 has one or more flat surfaces 533 for supporting the substrate and an opening (not shown) that extends along an axis of rotation. The susceptor 530 also includes a plurality of rotatable shafts 534 where each shaft is positioned in the opening of one of the segments 536. It should be noted that shaft can mean more than just a solid round, cylindrical shape, but also hexagonal, octagonal, square, hollow, etc.

The susceptor 530 may also include a heating and/or cooling mechanism 539 to maintain the susceptor 530 at a desired temperature. A temperature control device 526 is coupled to the heating and/or cooling mechanism 539 to monitor and regulate the temperature of susceptor 530. The susceptor 530 may not require grounding straps to provide RF grounding at the periphery of the susceptor 530 because the shafts 534 may be electrically connected to the wall 502 to provide grounding. The susceptor 530 may also be electrically biased, such with a commutator.

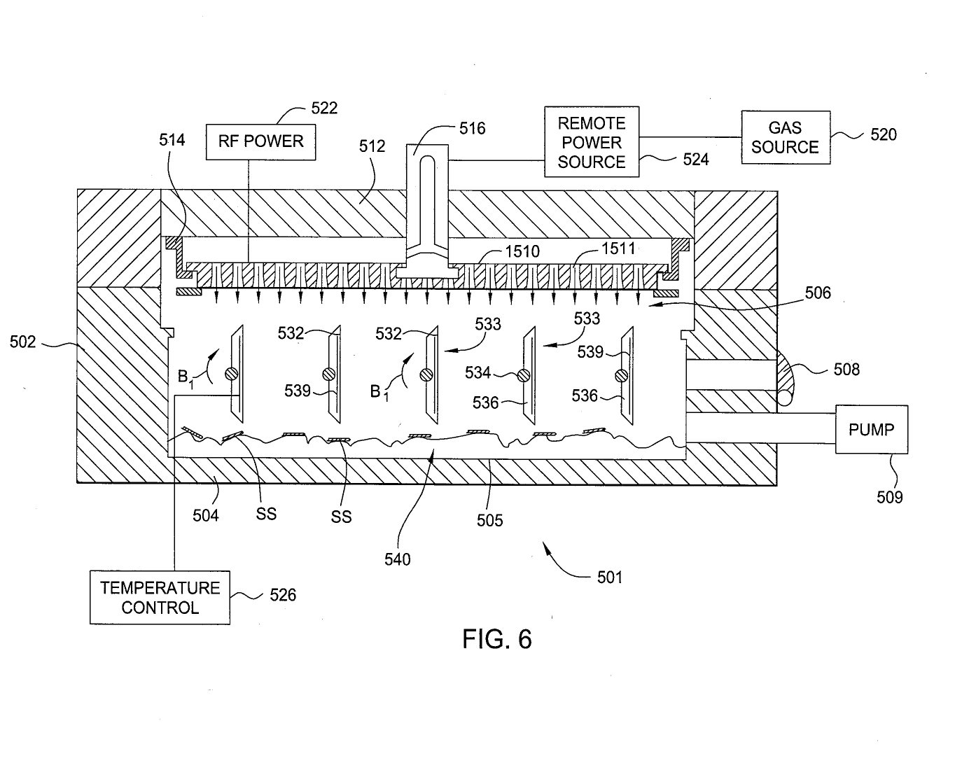

Each shaft may be connected to a drive mechanism 760 (FIG. 7) for rotating the shafts and thus rotating the plurality of segments (FIGS. 6 and 7). In one embodiment, the drive mechanism 760 may comprise a lead screw (not shown) and drive gears (not shown) coupled to a drive motor. In another embodiment, the drive mechanism 760 may be an integrated ferrofluidic seal or similar vacuum feedthrough (not shown) that passes through the wall 502, providing a vacuum seal, and a feed through spindle passing through the ferrofluidic seal that is coupled to a drive motor (not shown).

In another embodiment for rotating the segments 536 of the susceptor 530, one segment designated the master segment may be connected to the drive mechanism 760 for rotating the shaft 534 connected to the master segment. The remaining segments are then designated slave segments that are each connected to the master segment such that when the drive mechanism 760 rotates the master segment, each slave segment also rotates. In another embodiment, the susceptor 530 may also be coupled to a lift system to raise and lower the susceptor 530. For example, the lift system may be coupled to each shaft to vertically displace each shaft either collectively or individually.

The showerhead 510 is coupled to a backing plate 512 at its periphery by a suspension 514. The showerhead 510 may also be coupled to the backing plate by one or more center supports 516 to help prevent sag and/or control the straightness/curvature of the showerhead 510. A gas source 520 is coupled to the backing plate 512 to provide gas through the backing plate 512 and through the plurality of holes 511 in the showerhead 510 to the substrate support surface 532. A vacuum pump 509 is coupled to the PECVD chamber 501 to control the process volume 506 at a desired pressure. An RF power source 522 is coupled to the backing plate 512 and/or to the showerhead 510 to provide a RF power to the showerhead 510 so that an electric field is created between the showerhead and the substrate support so that a plasma may be generated from the gases between the showerhead 510 and the substrate support 530. Various RF frequencies may be used, such as a frequency between about 0.3 MHz and about 200 MHz. In one embodiment the RF power source is provided at a frequency of 13.56 MHz.

A remote plasma source 524, such as an inductively coupled remote plasma source, may also be coupled between the gas source and the backing plate. Between processing batches of substrates, a cleaning gas may be provided to the remote plasma source 524 so that a remote plasma is generated and provided to clean chamber components. The cleaning gas may be further excited by the RF power source 522 provided to the showerhead. Suitable cleaning gases include but are not limited to NF₃, F₂, and SF₆. Examples of remote plasma sources are disclosed in U.S. Pat. No. 5,788,778 issued Aug. 4, 1998 to Shang et al, which is incorporated by reference to the extent not inconsistent with the present disclosure.

As shown in FIG. 5, in one embodiment of the invention an apparatus for processing a substrate is provided. The apparatus includes a processing chamber 501 and a susceptor 530 located within the chamber 501. The susceptor 530 has a plurality of segments 536 aligned to form a substrate support surface 532. Each segment has one or more flat surfaces 533 for supporting a substrate S and an opening (not shown) that extends along an axis of rotation, such as a vertical axis of rotation as shown in FIG. 5. Each segment 536 has a plurality of rotatable shafts 534 positioned in the opening of one of the segments 536. The segments may have various polygonal cross-sectional shapes. For example, the segments in FIG. 5 have a cross-section that is trapezoidal. Other examples of various cross-sections are shown in FIGS. 7A-7C. For example a cross-section of the segments may be triangular. The plurality of segments 536 may be arranged to form a uniform substrate support surface aid in forming a uniform plasma above the susceptor 530. Without a uniform susceptor, the plasma formed above the substrate will change.

Although one exemplary chamber (a PECVD chamber) is shown in more detail, other chambers within the processing system 100 may also utilize the susceptor 530. For example, other processing chambers that may utilize the susceptor include a physical vapor deposition (PVD) chamber, a hot wire chemical vapor deposition (HWCVD) chamber, plasma nitridation (DPN) chamber, an ion implant/doping chamber, an atomic layer deposition (ALD) chamber, a plasma etching chamber, an annealing chamber, a rapid thermal oxidation (RTO) chamber, a rapid thermal annealing (RTA) chamber, a laser annealing chamber, a rapid thermal nitridation (RTN) chamber, a vapor etching chamber, a forming gas or hydrogen annealer, and/or a plasma cleaning chamber.

FIG. 6 illustrates a schematic cross-sectional view of one embodiment of a PECVD type processing chamber according to one embodiment described herein. The substrates S may crack, chip, break, or otherwise fracture during processing. Any substrate shards SS leftover after processing may remain on the susceptor. The susceptor may “self-clean” by rotating the shaft 534 a sufficient degree to dump any remaining shards SS or other debris onto the chamber floor 505, and create a residue 540 of broken substrates and debris.

FIGS. 7A-7C show another embodiment of the invention where the susceptor may also be used to transport substrates. Although only the susceptor 730 is shown, the susceptor 730 may also be used in various processing chambers such as PECVD chamber 501 of FIGS. 5 and 6. FIGS. 7A and 7B show a side view of a susceptor according to one embodiment described herein. FIG. 7C is a plan view of the susceptor illustrated in FIG. 7B in which substrates are transported according to one embodiment described herein.

An end effector 118 of a robot (such as robot 111 in previous figures adapted to transfer substrates among a plurality of processing chambers) having substrate conveyors 116 transports substrates S onto triangular cross-sectional shaped segments 736 of susceptor 730. In one embodiment of the invention, the susceptor segments 736 have a cross-sectional shape that enables transport of the substrates into and out of the processing chamber by rotating the susceptor segments, such as a triangular cross-sectional shape. Other possible shapes may include octagonal, pentagonal, hexagonal, etc. Any tips formed by the cross-sectional shape of the segment, such as the triangular cross-section having three tips, may be rounded tips so that sharp points would not touch the substrate.

A method of processing a batch of substrates S accordingly includes transferring at least one substrate S in the batch into a processing chamber, such as a PECVD chamber 501 shown in FIGS. 5 and 6, and onto a susceptor 730. The susceptor 730 includes a plurality of segments 736 aligned to form a substrate support surface 732. Each segment has one or more flat surfaces 733 for supporting the substrate and an opening (not shown) that extends along an axis of rotation. The susceptor also includes a plurality of rotatable shafts 734, each shaft 734 positioned in the opening of one of the segments 736. The method of processing a batch of substrates S also includes processing the at least one substrate S within the chamber, transferring the at least one substrate S out of the processing chamber and removing debris from the substrate support surface 732. The removing debris step includes rotating the segments 736 to dump any debris, such as glass shards SS, on the substrate support surface 732 onto a chamber floor 505 where it will remain during further processing. The previous steps in the method are repeated until the last substrate in the batch is processed.

In one embodiment of the method, transferring at least one substrate S in the batch into the processing chamber 501 includes placing the at least one substrate S onto one end of the susceptor 750 and rotating the segments to translationally move the at least one substrate S into a processing volume 506 of the chamber 501. The substrates S follow transfer path B₂ when the segments are rotated in direction B₁ as shown in FIG. 7B.

In another embodiment of the invention, the steps of transferring at least one substrate S out of the processing chamber 501 and removing debris, such as shards SS, from the substrate support surface 732 are combined by rotating the segments 736 to translationally move the at least one substrate S to one end of the susceptor 750 and out of a processing volume 506 of the chamber while also dumping any debris on the substrate support surface 732 onto a chamber floor 505, where it will remain during further processing. The segments 736 may be arranged to form a uniform substrate support surface. In another embodiment, a large processing chamber may be used enabling the susceptors to continuously transport substrates through the chamber while processing the substrates.

Sometimes the spacing between electrodes in a chamber may be a few millimeters. In one embodiment of the invention, the spacing between electrodes is changed by moving one electrode apart from the other electrode before rotating the susceptor. For example, the showerhead may be moved before rotating the segments of the susceptor. By moving the electrodes, optimization of the process spacing may be achieved.

The susceptor segments may be made from various materials such as metal, ceramic, aluminum, anodized aluminum, silicon carbide, silicon, or combinations thereof. The material chosen would depend on the process such as using a ceramic if a dielectric susceptor is desired.

The susceptor segments may be close together to prevent discontinuity of the susceptor. However, gaps between the segments may occur. Any gaps between each segment may be smaller than a substrate so that any substrate on the susceptor may be picked up and held on the tips of the segment, such as shown in FIG. 7B below. Alternatively, the segments could have another conveyance method such as lift pins and a fork. In another embodiment of the invention, a sensor, such as a camera or optical beam, indicates if any substrates have broken and left a piece behind. If the sensor indicates that a broken piece of the substrate has been left behind, the segments are rotated to dump the broken piece onto the chamber floor thereby removing broken pieces from the susceptor surface and processing region. Then during chamber maintenance, the broken pieces and any remaining debris on the chamber floor would be removed.

Some possible advantages of the present invention include automatic loading of substrates without the use of carriers for transporting substrates throughout a processing system. The present invention also enables “self-cleaning” by removing broken shards from the processing region with minimal interruption of the manufacturing process. Moreover, as processing chambers increase in size to take advantage of economies of scale, ever larger susceptors are necessary, a potentially very expensive limitation, such as when a susceptor must be machined out of special materials. However, the segmented susceptor according to embodiments of the present invention likely cost less to produce making larger processing chambers more economically feasible.

Any of the embodiments described herein can be combined or modified to incorporate aspects of the other embodiments. While the foregoing is directed to embodiments of the present invention, other and further embodiments of the invention may be devised without departing from the basic scope thereof, and the scope thereof is determined by the claims that follow.

1. A susceptor for an apparatus for processing a substrate, comprising:
a plurality of segments aligned to form a substrate support surface, each segment having one or more flat surfaces for supporting the substrate, and an opening that extends along an axis of rotation; and
a plurality of rotatable shafts, each shaft positioned in the opening of one of the segments.

2. The susceptor of claim 1, wherein a cross-section of each segment is polygonal.

3. The susceptor of claim 2, wherein a cross-section of each segment is trapezoidal.

4. The susceptor of claim 2, wherein a cross-section of each segment is triangular.

5. The susceptor of claim 1, wherein the segments are arranged to form a uniform substrate support surface.

6. The susceptor of claim 1, wherein the segments are made from material comprising metal, ceramic, aluminum, anodized aluminum, silicon carbide, silicon, or combinations thereof.

7. The susceptor of claim 1, wherein the segments are electrically biased.

8. The susceptor of claim 1, wherein the segments comprise a heating mechanism.

9. The susceptor of claim 1, wherein the segments comprise a cooling mechanism.

10. The susceptor of claim 1, wherein each shaft is connected to a drive mechanism for rotating the shafts.

11. The susceptor of claim 11, wherein the drive mechanism comprises a lead screw and drive gears coupled to a drive motor.

12. The susceptor of claim 11, wherein the drive mechanism comprises an integrated ferrofluidic seal and feedthrough spindle coupled to a drive motor.

13. The susceptor of claim 1, wherein one segment is master segment connected to a drive mechanism for rotating its shaft and the remaining segments are a slave segments, each connected to the master segment such that when the drive mechanism rotates the master segment, each slave segment also rotates.

14. The susceptor of claim 1, wherein the each shaft may be vertically displaced.

15. An apparatus for processing a substrate, comprising:
a processing chamber;
a susceptor located within the chamber, the susceptor further comprising:
a plurality of segments aligned to form a substrate support surface, each segment having one or more flat surfaces for supporting the substrate, and an opening that extends along an axis of rotation; and
a plurality of rotatable shafts, each shaft positioned in the opening of one of the segments.

16. The apparatus of claim 15, wherein a cross-section of the segments is trapezoidal.

17. The apparatus of claim 15, wherein a cross-section of the segments is triangular.

18. The apparatus of claim 15, wherein the segments are arranged to form a uniform substrate support surface.

19. The apparatus of claim 15, wherein the chamber is selected from a group of processing chambers consisting of a physical vapor deposition (PVD) chamber, a plasma enhanced chemical vapor deposition (PECVD) chamber, a hot wire chemical vapor deposition (HWCVD) chamber, plasma nitridation (DPN) chamber, an ion implant/doping chamber, an atomic layer deposition (ALD) chamber, a plasma etching chamber, an annealing chamber, a rapid thermal oxidation (RTO) chamber, a rapid thermal annealing (RTA) chamber, a laser annealing chamber, a rapid thermal nitridation (RTN) chamber, a vapor etching chamber, a forming gas or hydrogen annealer, and/or a plasma cleaning chamber.

20. A method of processing a batch of substrates, comprising:
transferring at least one substrate in the batch into a processing chamber and onto a susceptor, the susceptor comprising:
a plurality of segments aligned to form a substrate support surface, each segment having one or more flat surfaces for supporting the substrate, and an opening that extends along an axis of rotation; and
a plurality of rotatable shafts, each shaft positioned in the opening of one of the segments;
processing the at least one substrate within the chamber;
transferring the at least one substrate out of the processing chamber;
removing debris from the substrate support surface, the removing debris step comprising:
rotating the segments to dump any debris on the substrate support surface onto a chamber floor where it will remain during further processing;
repeating the previous steps until the last substrate in the batch is processed.

21. The method of claim 20, wherein transferring at least one substrate in the batch into the processing chamber comprises:
placing the at least one substrate onto one end of the susceptor; and
rotating the segments to translationally move the at least one substrate into a processing volume of the chamber.

22. The method of claim 20, wherein combining the steps of transferring at least one substrate out of the processing chamber and removing debris from the substrate support surface comprises:
rotating the segments to translationally move the at least one substrate to one end of the susceptor and out of a processing volume of the chamber while also dumping any debris on the substrate support surface onto a chamber floor where it will remain during further processing.

23. The method of claim 20, wherein a cross-section of the segments is trapezoidal.

24. The method of claim 20, wherein a cross-section of the segments is triangular.

25. The method of claim 20, wherein the segments are arranged to form a uniform substrate support surface.
